(19) United States
(12) Patent Application Publication
(10) Pub. No.: US 2021/0306580 A1
(43) Pub. Date: Sep. 30, 2021

(54) IMAGE SENSING DEVICE

(71) Applicant: SK hynix Inc., Icheon-si (KR)

(72) Inventor: Cha Young Lee, Icheon-si (KR)

(21) Appl. No.: 17/017,174

(22) Filed: Sep. 10, 2020

(30) Foreign Application Priority Data
Mar. 31, 2020 (KR) 10-2020-0039215

(51) Int. Cl. H04N 5/355; H01L 27/146

(52) U.S. Cl. CPC H04N 5/35563; H01L 27/1465; H01L 27/14621; H01L 27/14627

(57) ABSTRACT

An image sensing device includes a pixel array including hybrid pixel groups that are arranged in rows and columns, each of the hybrid pixel groups including a plurality of color detection pixels and a plurality of distance detection pixels. Each hybrid pixel group further includes first photoelectric conversion elements disposed in the color detection pixels and configured to perform photoelectric conversion of light incident upon the color detection pixels, second photoelectric conversion elements disposed in the distance detection pixels and configured to perform photoelectric conversion of light incident upon the distance detection pixels, first device isolation structures disposed between the first photoelectric conversion elements, second device isolation structures disposed between the second photoelectric conversion elements, first microlenses disposed over the first photoelectric conversion elements, and configured to allow incident light to be focused at the first photoelectric conversion elements, and a second microlens disposed over the second photoelectric conversion elements, and configured to allow incident light to be focused at the second device isolation structures.

### CROSS-REFERENCE TO RELATED APPLICATION

This patent document claims the priority and benefits of Korean patent application No. 10-2020-0039215, filed on Mar. 31, 2020, which is incorporated by reference in its entirety as part of the disclosure of this patent document.

### TECHNICAL FIELD

The technology and implementations disclosed in this patent document generally relate to an image sensing device.

### BACKGROUND

An image sensor is a device (or an element) for converting an optical image into electrical signals. With the recent development of automotive, medical, computer and communication industries, the demand for higher-performance image sensors has been increasing in various devices such as digital cameras, camcorders, personal communication systems (PCSs), game consoles, surveillance cameras, medical micro-cameras, robots, etc.

### SUMMARY

Various embodiments of the disclosed technology relate to an image sensing device in which pixels for color detection and other pixels for distance detection are incorporated into a single pixel array.

In accordance with an embodiment of the disclosed technology, an image sensing device may include a pixel array including hybrid pixel groups that are arranged in rows and columns, each of the hybrid pixel groups including a plurality of color detection pixels and a plurality of distance detection pixels. Each of the hybrid pixel groups may further include first photoelectric conversion elements disposed in the color detection pixels and configured to perform photoelectric conversion of light incident upon the color detection pixels, second photoelectric conversion elements disposed in the distance detection pixels and configured to perform photoelectric conversion of light incident upon the distance detection pixels, first device isolation structures disposed between the first photoelectric conversion elements, second device isolation structures disposed between the second photoelectric conversion elements, first microlenses disposed over the first photoelectric conversion elements, and configured to allow incident light to be focused at the first photoelectric conversion elements, and a second microlens disposed over the second photoelectric conversion elements, and configured to allow incident light to be focused at the second device isolation structures. In some implementations, the plurality of color detection pixels are configured to detect light of different colors to obtain color image information from incident light from a target object and the plurality of distance detection pixels are configured to detect incident light for measuring a distance between a location on the target object and a corresponding hybrid pixel group receiving the incident light from the location on the target object.

In accordance with another embodiment of the disclosed technology, an image sensing device may include a substrate including a color detection region and a distance detection region, first photoelectric conversion elements disposed in the color detection region and configured to perform photoelectric conversion of light in response to receiving light incident upon the color detection region, second photoelectric conversion elements disposed in the distance detection region and configured to perform photoelectric conversion of light in response to receiving light incident upon the distance detection region, first device isolation structures disposed between the first photoelectric conversion elements, second device isolation structures disposed between the second photoelectric conversion elements, color filters disposed over the first photoelectric conversion elements, at least one infrared (IR) transmission layer disposed over the second photoelectric conversion elements to allow transmission of IR light to reach the second photoelectric conversion elements, a grid structure disposed between the color filters and configured to prevent crosstalk from occurring between the color filters, first microlenses disposed over the color filters, and second microlenses disposed over the at least one infrared (IR) transmission layer. In some implementations, the color detection region is configured to obtain color image information from incident light from a target object and the distance detection region is configured to detect incident light for measuring a distance between a location on the target object and a corresponding second photoelectric conversion element receiving the incident light from the location on the target object.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example of a structure of a hybrid pixel group contained in a pixel array shown in FIG. 1 based on some implementations of the disclosed technology.

FIG. 3A is a cross-sectional view illustrating an example of the hybrid pixel group contained in the pixel array taken along the line X1-X1′ shown in FIG. 2 based on some implementations of the disclosed technology.

FIG. 3B is a cross-sectional view illustrating an example of the hybrid pixel group contained in the pixel array taken along the line X2-X2′ shown in FIG. 2 based on some implementations of the disclosed technology.

FIG. 4 is a cross-sectional view illustrating an example of the hybrid pixel group contained in the pixel array taken along the line X1-X1′ shown in FIG. 2 based on some other implementations of the disclosed technology.

### DETAILED DESCRIPTION

This patent document provides implementations and examples of an image sensing device that substantially addresses one or more issues due to limitations and disadvantages of the related art. Some implementations of the disclosed technology suggest designs of an image sensing device in which pixels for color detection and pixels for distance detection are incorporated into a single pixel array. The disclosed technology can be used for various implementations of image sensor devices which can be used to detect a color of a target object and a distance to the target object using only one sensing device, and can also be used to increase a light absorption rate in the pixel region needed for distance detection.

Reference will now be made in detail to certain embodiments, examples of which are illustrated in the accompanying drawings. Wherever possible, the same reference numbers will be used throughout the drawings to refer to the same or similar parts.

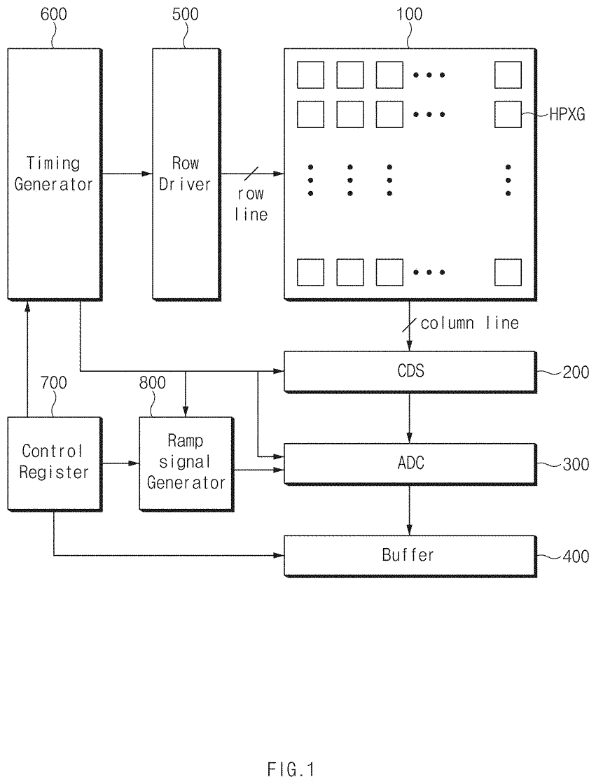

FIG. 1 is an example of a block diagram illustrating an image sensing device based on some implementations of the disclosed technology.

Referring to FIG. 1, the image sensing device may include a pixel array 100, a correlated double sampler (CDS) 200, an analog-to-digital converter (ADC) 300, a buffer 400, a row driver 500, a timing generator 600, a control register 700, and a ramp signal generator 800.

The pixel array 100 may include a plurality of hybrid pixel groups (HPXGs) consecutively arranged in a two-dimensional (2D) structure in which the hybrid pixel groups (HPXGs) are arranged in a first direction and a second direction perpendicular to the first direction. Each of the hybrid pixel groups (HPXGs) may include a plurality of unit pixels consecutively arranged in a two-dimensional (2D) structure.

The unit pixels may convert incident light into an electrical signal (e.g., a pixel signal) corresponding to the incident light by performing photoelectric conversion of the incident light, and may output the electrical signal through column lines based on a signal received from the row driver 500 through row lines. For example, each hybrid pixel group (HPXG) may include a plurality of color detection pixels to detect colors of incident light, and a plurality of distance detection pixels to detect a distance (i.e., depth) between the image sensor and a target object. Thus, each hybrid pixel group (HPXG) may include a hybrid structure in which the color detection pixels are combined with the distance detection pixels.

The correlated double sampler (CDS) 200 may sample electrical signals received from the pixels (PXs) of the pixel array 100. For example, the correlated double sampler (CDS) 200 may perform sampling of a reference voltage level and a voltage level of the received electrical image signal in response to a clock signal received from the timing generator 600, and may generate an analog signal corresponding to a difference between the reference voltage level and the voltage level of the received electrical image signal. The analog signal is sent to the analog-to-digital converter (ADC) 300 for digitalization.

The analog-to-digital converter (ADC) 300 may compare a ramp signal received from the ramp signal generator 800 with a sampling signal received from the correlated double sampler (CDS) 200, and may thus output a comparison signal indicating the result of comparison between the ramp signal and the sampling signal. The analog-to-digital converter (ADC) 300 may count a level transition time of the comparison signal in response to a clock signal received from the timing generator 600, and may output a count value indicating the counted level transition time to the buffer 400.

The buffer 400 may store each of the digital signals received from the analog-to-digital converter (ADC) 300, may sense and amplify each of the digital signals, and may output each of the amplified digital signals. Therefore, the buffer 400 may include a memory (not shown) and a sense amplifier (not shown). The memory may store the count value, and the count value may be associated with output signals of the plurality of unit pixels (PXs). The sense amplifier may sense and amplify each count value received from the memory.

The row driver 500 may drive the unit pixels (PXs) of the pixel array 100 in units of a row line in response to an output signal of the timing generator 600.

The timing generator 600 may generate a timing signal to control the row driver 500, the correlated double sampler (CDS) 200, the analog-to-digital converter (ADC) 300, and the ramp signal generator 800.

The control register 700 may generate control signals to control the ramp signal generator 800, the timing generator 600, and the buffer 400.

The ramp signal generator 800 may generate a ramp signal to sample output signals of the correlated double sampler (CDS) 200 based on a timing signal received from the timing generator 600 and a control signal received from the control register 700.

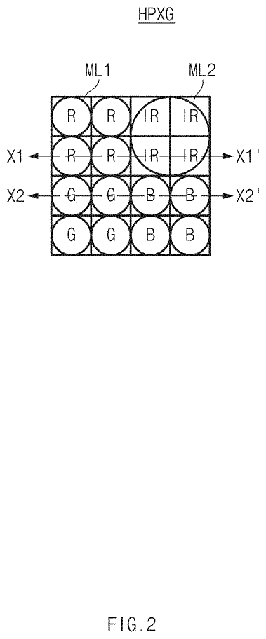

FIG. 2 is a plan view illustrating one example of a structure of the hybrid pixel group (HPXG) contained in the pixel array shown in FIG. 1 based on some implementations of the disclosed technology.

Referring to FIG. 2, the hybrid pixel group (HPXG) may include a plurality of unit pixels arranged in a two-dimensional (2D) structure. For example, the hybrid pixel group (HPXG) may include a plurality of unit pixels arranged in a (4×4) array structure including four rows and four columns. In this case, the plurality of unit pixels may include a plurality of color detection pixels and a plurality of distance detection pixels. For example, each hybrid pixel group (HPXG) may include a combination structure in which the plurality of color detection pixels are combined with the plurality of distance detection pixels.

The plurality of color detection pixels in each hybrid pixel group may include different color detection pixel regions or subgroups with color filters to select their respective colors of light for sensing, for example, a red (R) detection pixel region of R detection pixels to detect red light from the incident light, a green (G) detection pixel region of G detection pixels to detect green light from the incident light, and a blue (B) detection pixel region of B detection pixels to detect blue light from among the incident light. In addition, the plurality of distance detection pixels in each hybrid pixel group can be structured to measure a distance between an image sensor and a target object based on a suitable distance measuring technique, e.g., an optical time-of-flight (TOF) distance measurement technique and this distance measurement is embedded in each hybrid pixel group so different hybrid pixel groups so structured can measure different distances from different locations of the target object for obtaining not only 2D image information of the target object but also the depth profile across different hybrid pixel groups. In the example in FIG. 2 and other examples, such distance detection pixels may be implemented to include, as a specific example,

IR detection pixels to detect infrared (IR) light (or IR ray).

Each hybrid pixel group (HPXG) may include an array structure in which the plurality of unit pixels, which may have the same or similar characteristics, is arranged contiguous to one another. For example, the hybrid pixel group (HPXG) may include four R detection pixels (e.g., R pixel group) arranged in a (2×2) array structure in which the four R detection pixels are contiguous to one another, four G detection pixels (e.g., G pixel group) arranged in a (2×2) array structure in which the four G detection pixels are contiguous to one another, four B detection pixels (e.g., B pixel group) arranged in a (2×2) array structure in which the four B detection pixels are contiguous to one another, and four infrared (IR) detection pixels (e.g., IR pixel group) arranged in a (2×2) array structure in which the four IR detection pixels are contiguous to one another.

In this case, the R pixel group, the G pixel group, the B pixel group, and the IR pixel group may be formed in a shape in which any one of G pixel groups in a Bayer pattern is replaced with the IR pixel group. For example, the R pixel group, the G pixel group, the B pixel group, and the IR pixel group may be arranged in an R-G-IR-B or R-IR-G-B arrangement structure by replacing any one of G pixel groups of the R-G-G-B Bayer pattern with the IR pixel group. Although FIG. 2 has exemplarily disclosed the G pixel group located at an upper right portion of the hybrid pixel group (HPXG) is replaced with the IR pixel group, but other implementations are also possible. For example, the G pixel group located at a lower left portion of the hybrid pixel group (HPXG) instead of the G pixel group located at the upper right portion of the hybrid pixel group can be replaced with the IR pixel group.

In the hybrid pixel group (HPXG), a single separate microlens (ML1) may be independently formed in each of the color detection pixels of the R pixel group, the G pixel group, and the B pixel group. In the IR pixel group, a single large-sized microlens (ML2) formed to cover all of four IR detection pixels may be formed.

In this case, a grid structure may not be formed between the IR detection pixels of the IR pixel group. The microlens (ML2) may be formed in a manner that light having penetrated the microlens (ML2) is focused at a device isolation structure disposed between the photoelectric conversion elements without being focused at the photoelectric conversion element of the IR detection pixel. As described above, in the IR pixel group, light having penetrated the microlens (ML2) is focused at the device isolation structure, resulting in an increased length of an optical path of the incident light (i.e., IR light). For example, IR light incident upon the IR pixel group may be multi-reflected by device isolation structures of the IR detection pixel, such that the optical path contained in the IR detection pixel can increase in length. The microlens (ML1) may be formed in a manner that light having penetrated the microlens (ML1) can be focused at the photoelectric conversion element of the corresponding color detection pixel.

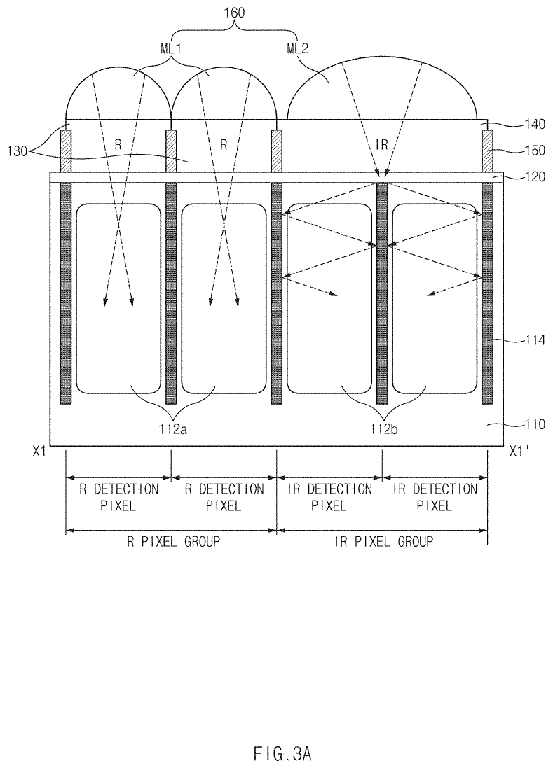

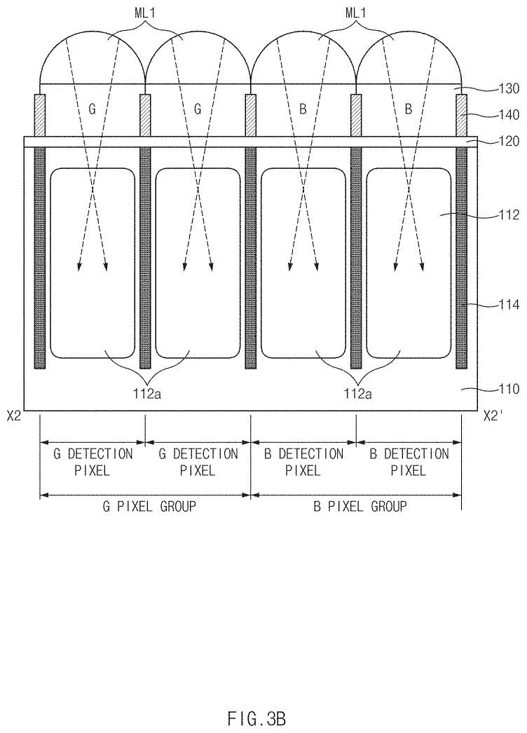

FIG. 3A is a cross-sectional view illustrating the hybrid pixel group contained in the pixel array taken along the line X1-X1′ shown in FIG. 2 based on some implementations of the disclosed technology. FIG. 3B is a cross-sectional view illustrating the hybrid pixel group contained in the pixel array taken along the line X2-X2′ shown in FIG. 2 based on some implementations of the disclosed technology. In FIGS. 3A and 3B, each of dotted arrows may denote an example of a light propagation path.

Referring to FIGS. 3A and 3B, the hybrid pixel group (HPXG) may include a substrate layer 110, a buffer layer 120, a color filter layer 130, an infrared (IR) transmission layer 140, a grid structure 150, and a lens layer 160.

The substrate layer 110 may include a semiconductor substrate. The substrate layer 110 may be in a monocrystalline state, and may include a silicon-containing material. The semiconductor substrate 110 may include P-type impurities.

In the semiconductor substrate 110, photoelectric conversion elements 112a of the color detection pixels and the photoelectric conversion elements 112b of the IR detection pixels are included. The photoelectric conversion elements 112a of the color detection pixels are configured to perform photoelectric conversion of light incident upon the color detection pixels (e.g., R detection pixels, G detection pixels, and B detection pixels). The photoelectric conversion elements 112b of the IR detection pixels are configured to perform photoelectric conversion of light incident upon the IR detection pixels. In addition, the semiconductor substrate 110 may include the device isolation structures 114 formed between the photoelectric conversion elements 112a and 112b so as to isolate the photoelectric conversion elements 112a and 112b from each another.

Each of the photoelectric conversion elements 112a and 112b may include an organic or inorganic photosensing material. Each of the photoelectric conversion elements 112a and 112b may include impurity regions vertically stacked within the substrate layer 110. For example, each of the photoelectric conversion elements 112a and 112b may include a photodiode in which an N-type impurity region and a P-type impurity region are vertically stacked. The N-type impurity region and the P-type impurity region may be formed by ion implantation.

The device isolation structure 114 may include a Deep Trench Isolation (DTI) structure. Although the photodiode is described as the example included in the photoelectric conversion elements 112a and 112b, other implementations are also possible. For example, the photoelectric conversion elements 112a and 112b may include, for example, photogates, phototransistors, photoconductors, or some other photosensitive structures capable of generating photocharges in response to received light.

The buffer layer 120 may operate as a planarization layer to remove a step difference formed over the substrate layer 110. In addition, the buffer layer 120 may operate as an anti-reflection film to allow incident light received through the lens layer 160 and the IR transmission layer 140 to pass therethrough. The buffer layer 120 may be formed of or include a multilayer structure formed by stacking different materials having different refractive indexes. For example, the buffer layer 120 may include a multilayer structure formed by stacking at least one nitride film and at least one oxide film.

The color filter layer 130 may be included in the color detection pixels of the hybrid pixel group (HPXG). The color filter 130 may be disposed over the buffer layer 120 to correspond to photoelectric conversion elements 112a of the color detection pixels. The color filter layer 130 may include a plurality of color filters that filters visible light selected from incident light received through the microlens (ML1) of the lens layer 160 and thus transmits only the selected visible light. For example, the color filter layer 130 may include a plurality of red color filters (Rs), a plurality of green color filters (Gs), and a plurality of blue color filters (Bs). Each red color filter (R) may transmit only red light from among RGB lights of visible light. Each green color filter (G) may transmit only green light from among RGB lights of visible light. Each blue color filter (B) may transmit only blue light from among RGB lights of visible light. The color filter layer 130 may include a quadrature structure in which four color filters having the same color are arranged in a (2×2) array structure as shown in FIG. 2. Alternatively, the color filter layer 130 may include a plurality of cyan filters, a plurality of yellow filters, and a plurality of magenta filters. Each of the color filters may include a photoresist material having the corresponding color. For example, each color filter may include a photoresist material having a colorant of the corresponding color.

The IR transmission layer 140 may be included in the IR detection pixels of the hybrid pixel group (HPXG). The IR transmission layer 140 may be disposed over the buffer layer 120 to spatially correspond to photoelectric conversion elements 112b of the IR detection pixels. The IR transmission layer 140 may transmit infrared (IR) light incident through the microlens (ML2) of the lens layer 160. Various dielectric materials such as silicon dioxide or silicon nitride exhibit undesired high optical absorption of IR light for the IR detection pixels and thus the material for the IR transmission layer 140 is selected to be sufficiently transmissive. The IR transmission layer 140 may include organic materials. For example, the IR transmission layer 140 may include a photoresist material having no colorant. The IR transmission layer 140 of each hybrid pixel group (HPXG) may be formed as a single layer (or a single film).

The grid structure 150 may be disposed between the contiguous color filters of the color detection pixels, such that the grid structure 140 can prevent optical crosstalk from occurring between the color filters. The grid structure 150 may not be formed between the

IR detection pixels. For example, in order to allow infrared (IR) light having penetrated the microlens (ML2) of the IR pixel group to be focused at the device isolation structure 114, the IR transmission layer 140 of the IR detection pixels does not include a grid structure between IR detection pixels.

The lens layer 160 may converge incident light received from the outside, and may transmit the converged light to the color filter layers 130 or the IR transmission layers 150. The lens layer 150 may include a first microlens (ML1) disposed over the color filter layer 130, and a second microlens (ML2) disposed over the IR transmission layer 140. A microlens (ML1) may be formed for each color detection pixel, and may allow the incident light to be focused at the photoelectric conversion element 112 of the corresponding color detection pixel. Only one microlens (ML2) may be formed for each IR pixel group. For example, the IR pixel group may be designed in a manner that one microlens (ML2) can cover all of the four IR detection pixels. In this case, the microlens (ML2) may be formed in a manner that incident light can be focused at the device isolation structure 114 disposed between the IR detection pixels.

As described above, in the IR pixel group, light (e.g., IR light) having penetrated the microlens (ML2) may be focused at the device isolation structure 114 that is disposed around a middle portion of the IR pixel group. There are more device isolation structures 114 disposed in the IR pixel group, for example, along external sides of the photoelectric conversion elements in the IR pixel group. The device isolation structures 114 include material that reflect light. Thus, IR lights can be multi-reflected by the device isolation structures 114 in the IR pixel group and the optical path can be increased in length as shown in FIG. 3A. Therefore, most IR lights each having a long wavelength may not penetrate the substrate layer 110, and can be photoelectrically converted by the photoelectric conversion element 112.

In some implementations, the image sensing device based on some implementations of the disclosed technology can include both of the color detection pixel group and the IR pixel group. By partially removing the grid structure from the IR pixel group and adjusting focusing of the microlenses disposed in the IR pixel group, the image sensing device can perform both the color detection and the distance detection without additional fabrication processing.

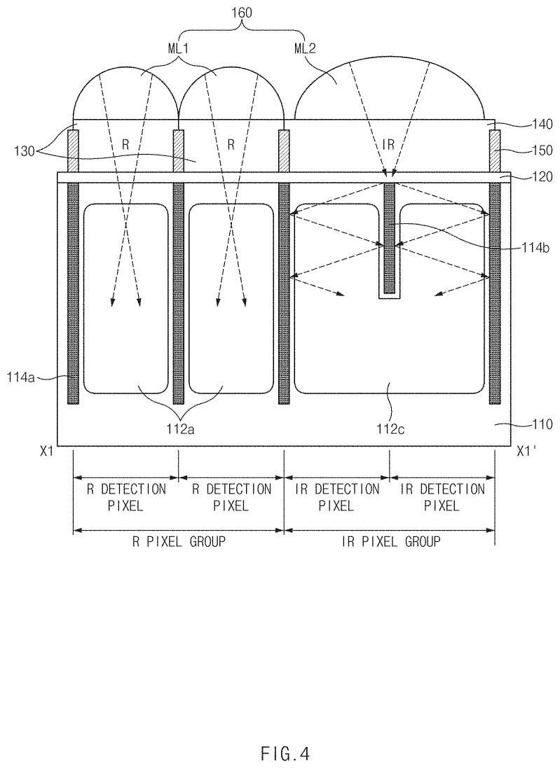

FIG. 4 is a cross-sectional view illustrating an example of the hybrid pixel group (HPXG) contained in the pixel array taken along the line X1-X1′ shown in FIG. 2 based on some other implementations of the disclosed technology.

Referring to FIG. 4, the device isolation structure 114b formed between the IR detection pixels in the IR pixel group of the hybrid pixel group (HPXG) may have a shorter length (depth) than other device isolation structures 114a.

The device isolation structure 114b between the IR detection pixels of the IR pixel group may reflect light that is focused by the microlens (ML2) and incident on the substrate layer 110. As shown in FIG. 4, the light reflected by the device isolation structure 114b proceeds towards the device isolation structures 114a that are disposed around boundaries of the photoelectric conversion element 112c and the device isolation structures 114b may then re-reflect the light reflected by the device isolation structures 114a. The device isolation structure 114b may be formed to have a predetermined length such that the optical path of IR light can increase enough to be photoelectrically converted by the photoelectric conversion element 112c.

In some implementations, the photoelectric conversion element 112c formed in the IR pixel group may be formed to extend to a lower region of the device isolation structure 114b.

The image sensing device based on some implementations of the disclosed technology can detect a color image of a target object and a distance to a target object using only one sensing device, and can increase a light absorption rate in the pixel region needed for distance detection.

Those skilled in the art will appreciate that the embodiments may be carried out in other specific ways than those set forth herein In addition, claims that are not explicitly presented in the appended claims may be presented in combination as an embodiment or included as a new claim by a subsequent amendment after the application is filed.

Although a number of illustrative embodiments have been described, it should be understood that numerous other modifications and embodiments can be made based on what is disclosed in this patent document.

What is claimed is:

1. An image sensing device comprising:
a pixel array including hybrid pixel groups that are arranged in rows and columns, each of the hybrid pixel groups including a plurality of color detection pixels and a plurality of distance detection pixels,
wherein each of the hybrid pixel groups further includes:
first photoelectric conversion elements disposed in the color detection pixels and configured to perform photoelectric conversion of light incident upon the color detection pixels;
second photoelectric conversion elements disposed in the distance detection pixels and configured to perform photoelectric conversion of light incident upon the distance detection pixels;
first device isolation structures disposed between the first photoelectric conversion elements;
second device isolation structures disposed between the second photoelectric conversion elements;
first microlenses disposed over the first photoelectric conversion elements, and configured to allow incident light to be focused at the first photoelectric conversion elements; and
a second microlens disposed over the second photoelectric conversion elements, and configured to allow incident light to be focused at the second device isolation structures.

2. The image sensing device according to claim 1, wherein:
the first microlenses are disposed over the first photoelectric conversion elements in one-to-one correspondence with the first photoelectric conversion elements.

3. The image sensing device according to claim 1, wherein the second microlens corresponds to a single microlens disposed to cover all of the second photoelectric conversion elements.

4. The image sensing device according to claim 1, further comprising:
color filters disposed between the first photoelectric conversion elements and the first microlenses; and
at least one infrared (IR) transmission layer disposed between the second photoelectric conversion elements and the second microlens.

5. The image sensing device according to claim 4, further comprising:
a grid structure disposed between the color filters included in the color detection pixels and not included in the distance detection pixels, the grid structure configured to prevent crosstalk from occurring between the color filters.

6. The image sensing device according to claim 1, wherein the plurality of color detection pixels includes:
first to third color detection pixels, each of the first to third color detection pixels arranged in a (2×2) array structure including two columns and two rows.

7. The image sensing device according to claim 1, wherein the distance detection pixels are arranged in a (2×2) array structure including two columns and two rows.

8. The image sensing device according to claim 1, wherein the second device isolation structures include a second device isolation structure having a shorter length than those of the first device isolation structures.

9. The image sensing device according to claim 1, wherein at least one of the second photoelectric conversion elements has a bottom surface positioned lower than those of the second device isolation structures.

10. The image sensing device according to claim 1, wherein the second device isolation structures include material that reflects light.

11. An image sensing device comprising:
a substrate including a color detection region and a distance detection region;
first photoelectric conversion elements disposed in the color detection region of the substrate and configured to perform photoelectric conversion of light in response to receiving light incident upon the color detection region;
second photoelectric conversion elements disposed in the distance detection region of the substrate and configured to perform photoelectric conversion of light in response to receiving light incident upon the distance detection region;
first device isolation structures disposed between the first photoelectric conversion elements;
second device isolation structures disposed between the second photoelectric conversion elements;
color filters disposed over the first photoelectric conversion elements;
at least one infrared (IR) transmission layer disposed over the second photoelectric conversion elements to allow transmission of IR light to reach the second photoelectric conversion elements;
a grid structure disposed between the color filters and configured to prevent crosstalk from occurring between the color filters;
first microlenses disposed over the color filters; and
a second microlens disposed over the at least one infrared (IR) transmission layer.

12. The image sensing device according to claim 11, wherein:
the first microlenses are disposed over the color filters in one-to-one correspondence with the color filters.

13. The image sensing device according to claim 11, wherein the second microlens corresponds to a single microlens disposed to cover the at least one infrared (IR) transmission layer.

14. The image sensing device according to claim 11, wherein the second device isolation structures include a second device isolation structure having a shorter length than those of the first device isolation structures.

15. The image sensing device according to claim 11, wherein at least one of the second photoelectric conversion elements extends to be located lower than the second device isolation structures.

16. The image sensing device according to claim 11, wherein at least one of the second device isolation structures has a length such that light reflected by the second device isolation structure is received by the second photoelectric conversion elements and converted by the second photoelectric conversion elements.

17. The image sensing device according to claim 11, wherein the second device isolation structures include material that reflects light.

18. The image sensing device according to claim 11, wherein no grid structure is disposed in the IR transmission layer.
